(19) United States
(12) Patent Application Publication
(10) Pub. No.: US 2019/0191575 A1
(43) Pub. Date: Jun. 20, 2019

(54) FIRE AND WATER RESISTANT ANKLE MONITOR

(71) Applicant: Keisha Tawn Lavergne, Hankamer, TX (US)

(72) Inventor: Keisha Tawn Lavergne, Hankamer, TX (US)

(21) Appl. No.: 15/841,661

(22) Filed: Dec. 14, 2017

(51) Int. Cl. H05K 5/02; H05K 5/00

(52) U.S. Cl. CPC H05K 5/0217; G08B 21/0269; H05K 5/0086; H05K 5/0221

(57) ABSTRACT

A fire and water proof ankle monitor comprising a CPU operating the various components of the ankle monitor comprised of a communication module, a global positioning system module, a tamper sensor, a power system, and a strap lock. An encapsulating casing comprising a one-piece polycarbonate structure sealing the components so as to totally isolate the components.

### CROSS-REFERENCE TO RELATED APPLICATION(S)

Not applicable

### BACKGROUND OF THE INVENTION

### 1. Field of Invention

The present invention relates to the field of ankle monitors, more particularly to an ankle monitor with enhanced fire and water resistance.

### 2. Description of Related Art

Ankle monitors are widely utilized by the justice system to monitor individual with pending criminal charges released from jail on bail, facilitate monitoring individuals on home arrest, and monitoring individuals on parole or probation. They have also begun to see use monitoring of individuals with mental impairments such as Alzheimer or dementia.

A drawback to current ankle monitors is susceptibility to fire and water damage. Fire proofing and water proofing could offer enhanced utility in disaster situation to rapidly locate missing mentally impaired individuals equipped with ankle monitors. However, current ankle monitors can be damaged by fire or water immersion, which can render them inoperative in a mass disaster.

Based on the foregoing, there is a need in the art for an improved ankle monitor which offers enhanced resistance to fire and water damage.

### SUMMARY OF THE INVENTION

A fire and water proof ankle monitor comprising a CPU operating the various components of the ankle monitor comprised of a communication module, a global positioning system module, a tamper sensor, a power system, and a strap lock. An encapsulating casing comprising a one-piece polycarbonate structure sealing the components so as to totally isolate the components.

An ankle strap comprising steel and secured in a locked configuration by the strap lock.

Constructing the casing using injection molding.

Constructing the casing using thermoforming.

A first, innermost component housing surrounded by the casing.

The first, innermost component housing comprises a thin metal, plastic, or acrylic.

The thin metal comprises steel or aluminum.

Advantages:

1. Improved fire resistance.

2. Improved water resistance.

3. Improved chances of rescue during disasters.

4. Improved chances of solving crimes.

5. Reduced incidence of missing persons and unsolved crimes.

The foregoing, and other features and advantages of the invention, will be apparent from the following, more particular description of the preferred embodiments of the invention, the accompanying drawings, and the claims.

### BRIEF DESCRIPTION OF THE DRAWINGS

For a more complete understanding of the present invention, the objects and advantages thereof, reference is now made to the ensuing descriptions taken in connection with the accompanying drawings briefly described as follows.

FIG. 1 is a prior art view of the home ankle monitor system, according to an embodiment of the present invention;

FIG. 2 is a schematic block diagram of the ankle monitor, according to an embodiment of the present invention.

### DETAILED DESCRIPTION OF PREFERRED EMBODIMENTS

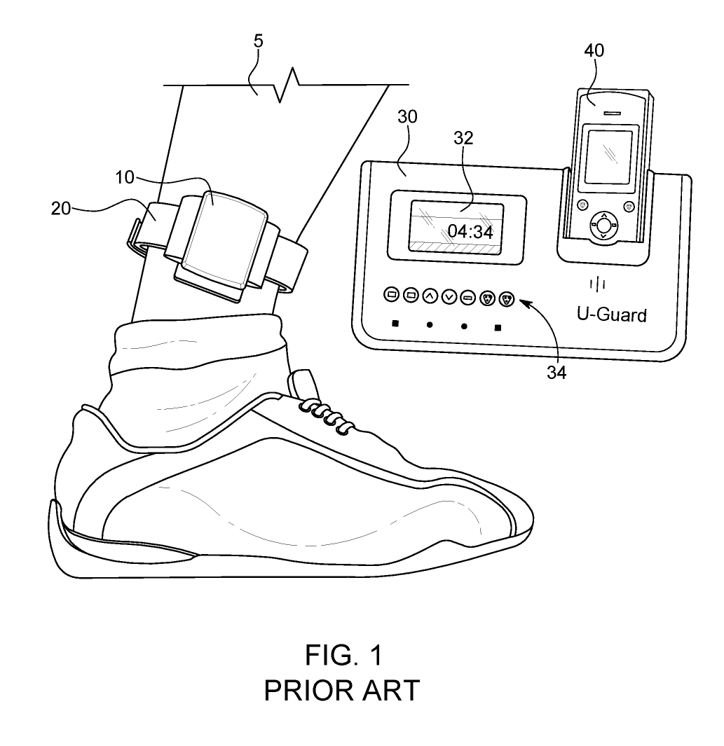

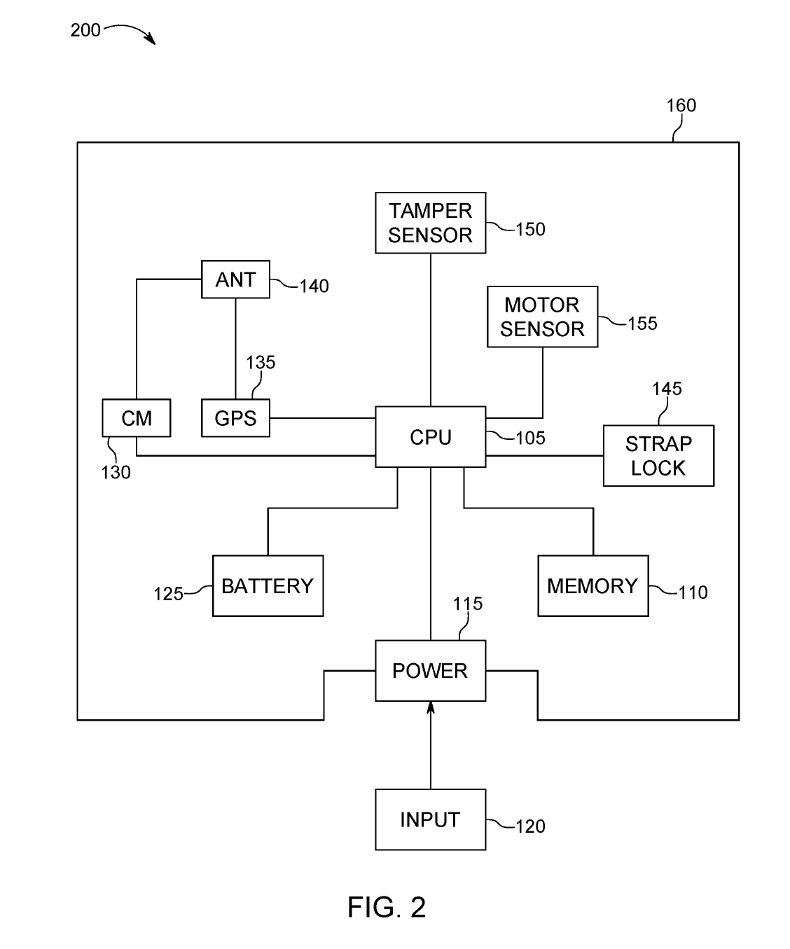

Preferred embodiments of the present invention and their advantages may be understood by referring to FIGS. 1-2, wherein like reference numerals refer to like elements.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will now be described in detail with reference to embodiments thereof as illustrated in the accompanying drawings.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic. Further, repeated use of the phrase “in one embodiment,” or “in an exemplary embodiment,” do not necessarily refer to the same embodiment, although they may.

Headings provided herein are for convenience and are not to be taken as limiting the disclosure in any way.

The enumerated listing of items does not imply that any or all of the items are mutually exclusive, unless expressly specified otherwise.

The terms “a”, “an” and “the” mean “one or more”, unless expressly specified otherwise.

Devices or system modules that are in at least general communication with each other need not be in continuous communication with each other, unless expressly specified otherwise. In addition, devices or system modules that are in at least general communication with each other may communicate directly or indirectly through one or more intermediaries.

The computer memories in the various disclosed devices may store computer executable instructions. Each disclosed computer/communication device such as computer, a server, a system node, a smart phone, a tablet, or similar device able to execute computer code and/or process digital, electronic data may execute computer executable instructions. The computer executable instructions may be included in computer code. The computer code may be stored in the various device memories. The computer code may be written in any computer language comprising the prior art. The memory may be a non-transitory tangible storage media. Sophisticated computer apps have increasingly become available, with downloaded executable software code (e.g., the Apple® Store) providing for configuring a mobile device, such as a smart phone or tablet, to perform a plethora of functions.

The computer code may be logic encoded in one or more tangible media or one or more non-transitory tangible media for execution by the processor in the devices. Logic encoded in one or more tangible media for execution may be defined as instructions that are executable by the processor and that are provided on the computer-readable storage media, memories, or a combination thereof. Logic may include a software controlled microprocessor, an application specific integrated circuit (ASIC), an analog circuit, a digital circuit, a programmed logic device, a memory device containing instructions, and the like. The instructions may be stored on any computer readable medium comprising the prior art from which a computer, a processor, or other electronic device can read. This may include a computer data disk or the like storing computer code that can be used to configure a memory associated with a computer, a processor, or other electronic device.

The processor may include a general processor, digital signal processor, ASIC, field programmable gate array, analog circuit, digital circuit, central processing unit (CPU), micro-processor unit (MPU), micro-controller unit (MCU), combinations thereof, or other now known processor. The processor may be a single device or combinations of devices, such as associated with a network or distributed processing. The processor may be responsive to or operable to execute instructions stored as part of software, hardware, integrated circuits, firmware, micro-code or the like. The functions, acts, methods or tasks illustrated in the figures or described herein may be performed by the processor executing instructions stored in the memory.

A description of an embodiment with several components in communication with each other does not imply that all such components are required. On the contrary a variety of optional components are described to illustrate the wide variety of possible embodiments of the present invention.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

The present invention will now be described in detail with reference to embodiments thereof as illustrated in the accompanying drawings.

FIG. 1 is a prior art view of a home ankle monitor system 100. A person 5 being monitored by an ankle monitor 10 secured to the person 5 using a strap 20 locked in a receptacle of the ankle monitor 10. Typically, the strap 20 comprises a steel band or cable resistant to tampering or cutting (e.g., case hardened or tool steel). The monitor 10 further communicates with a home base unit 30 that can include an interface 32 to monitor and provide control inputs to the monitor 10. Control inputs 34 can interact with interface 32. Further, the home base unit 30 includes a phone 40 for communicating with a monitoring service.

FIG. 2 shows a schematic block diagram of an ankle monitor 200 according to the invention. Internal components of the ankle monitor 200 can include a central processing unit (CPU) 105, a memory 110, a power module 115 that comprises an exterior input 120 for connecting to a charger, and a battery 125, which can interface with the power module 115. The CPU 105 can also interface an associated communication module (CM) 130 for wireless communication using antenna 140. The wireless communication can include communicating with home base unit 10, communicating over a WiFi connection, and mobile phone cellular systems, and can further include Internet access. CPU 105 can also interface with a global satellite positioning system (GPS) 135, which can further communicate with a GPS satellite array using antenna 140. CPU 105 further interfaces with strap lock 145 to lock and unlock strap 20. Also interfaced with CPU 105 is a motion sensor 155 for detecting movement of a wearer and a tamper sensor 150 for detecting tampering with the ankle monitor 200 or the ankle strap 20. Finally, the ankle monitor 200 includes a casing 160. Casing 160 encapsulates the ankle monitor 200 to totally isolate the components from the exterior to include isolating the power module 115 so that water cannot enter the casing 115.

In an embodiment, the casing 160 comprises a one-piece construction made from polycarbonate. The casing 160 preferably is formed by injection molding to completely surround and encapsulate the components of the ankle monitor 200 and isolate the components from the exterior. In another embodiment, casing 160 can comprise a second encapsulating structure formed over a first, innermost component housing comprising a plastic or acrylic housing that encloses the components of ankle monitor 200. Other housing materials are possible including a thin sheet metal such as steel or aluminum. In an embodiment, rather than using injection molding, casing 160 can be formed by thermoforming to encapsulate the components.

The one-piece polycarbonate construction of casing 160 can make the components both fire and water proof.

The invention has been described herein using specific embodiments for the purposes of illustration only. It will be readily apparent to one of ordinary skill in the art, however, that the principles of the invention can be embodied in other ways. Therefore, the invention should not be regarded as being limited in scope to the specific embodiments disclosed herein, but instead as being fully commensurate in scope with the following claims.

I claim:

1. A fire and water proof ankle monitor, comprising:
a CPU operating the various components of the ankle monitor comprised of a communication module, a global positioning system module, a tamper sensor, a power system, and a strap lock;
an encapsulating casing comprising a one-piece polycarbonate structure sealing the components so as to totally isolate the components.

2. The fire and water proof ankle monitor of claim 1, further comprising:
an ankle strap comprising steel and secured in a locked configuration by the strap lock.

3. The fire and water proof ankle monitor of claim 1, further comprising:
constructing the casing using injection molding.

4. The fire and water proof ankle monitor of claim 1, further comprising:
constructing the casing using thermoforming.

5. The fire and water proof ankle monitor of claim 1, further comprising:
a first, innermost component housing surrounded by the casing.

6. The fire and water proof ankle monitor of claim 5, wherein the first, innermost component housing comprises a thin metal, plastic, or acrylic.

7. The fire and water proof ankle monitor of claim 6, wherein the thin metal comprises steel or aluminum.
